(19) United States
(12) Patent Application Publication
(10) Pub. No.: US 2026/0144109 A1
(43) Pub. Date: May 21, 2026

(54) SEMICONDUCTOR PACKAGE INCLUDING ADHESIVE LAYER

(71) Applicant: Samsung Electronics Co., Ltd., Suwon-si (KR)

(72) Inventor: Jiyoung Yoon, Suwon-si (KR)

(21) Appl. No.: 19/388,612

(22) Filed: Nov. 13, 2025

(30) Foreign Application Priority Data
Nov. 19, 2024 (KR) 10-2024-0164869

(51) Int. Cl. H01L 23/498; H01L 23/00

(52) U.S. Cl. CPC H10W 70/65; H10W 90/401; H10W 74/15; H10W 90/724; H10W 90/734; H10W 90/794

(57) ABSTRACT

A semiconductor package includes a lower redistribution structure including lower redistribution layers, lower insulating layers covering the lower redistribution layers, and a first adhesive layer between the lower insulating layers, a lower chip structure on the lower redistribution structure, an encapsulant covering the lower chip structure, an underbump metallurgy (UBM) layer below the lower redistribution structure, and an external connection terminal electrically connected to the UBM layer. The lower redistribution layers include a first lower redistribution layer in contact with the UBM layer, the first lower redistribution layer including a first interconnection layer and a first plating layer covering at least a portion of the first interconnection layer. The first adhesive layer is in contact with the first plating layer of the first lower redistribution layer. A surface roughness of the first plating layer is greater than a surface roughness of the first interconnection layer.

### CROSS-REFERENCE TO RELATED APPLICATION(S

This application claims benefit of priority to Korean Patent Application No. 10-2024-0164869 filed on November 19, 2024, in the Korean Intellectual Property Office, the disclosure of which is incorporated herein by reference in its entirety.

### BACKGROUND

As demand for implementation of high performance, high speed, and/or multifunctionalization of semiconductor devices increases, a degree of integration of semiconductor devices has been increasing. In manufacturing semiconductor devices having a fine pattern corresponding to the trend for a high degree of integration of semiconductor devices, it may be desired to implement patterns having a fine width or a fine separation distance.

### SUMMARY

An aspect of the present disclosure provides a semiconductor package including an adhesive layer in contact with a lower redistribution layer.

According to an aspect of the present disclosure, a semiconductor package includes a lower redistribution structure including lower redistribution layers, lower insulating layers covering the lower redistribution layers, and a first adhesive layer between the lower insulating layers, a lower chip structure disposed on the lower redistribution structure, the lower chip structure electrically connected to the lower redistribution layers, an encapsulant covering the lower chip structure, an underbump metallurgy (UBM) layer disposed below the lower redistribution structure, the UBM layer electrically connected to the lower redistribution layers, and an external connection terminal electrically connected to the UBM layer. The lower redistribution layers may include a first lower redistribution layer in contact with the UBM layer, the first lower redistribution layer including a first interconnection layer and a first plating layer covering at least a portion of the first interconnection layer. The first adhesive layer may be in contact with the first plating layer of the first lower redistribution layer. A surface roughness of the first plating layer may be greater than a surface roughness of the first interconnection layer.

According to another aspect of the present disclosure, a semiconductor package includes a lower redistribution structure including lower redistribution layers, lower insulating layers covering the lower redistribution layers, and a first adhesive layer between the lower insulating layers, a lower chip structure disposed on the lower redistribution structure, the lower chip electrically connected to the lower redistribution layers, an encapsulant covering the lower chip structure, a UBM layer disposed below the lower redistribution structure, the UBM layer electrically connected to the lower redistribution layers, and an external connection terminal electrically connected to the UBM layer. The lower redistribution layers may include a first lower redistribution layer in contact with the UBM layer. The first adhesive layer may be in contact with the first lower redistribution layer. At least one surface of the first lower redistribution layer may include a plurality of recesses. A surface of the first adhesive layer may include a plurality of recesses.

According to another aspect of the present disclosure, a semiconductor package includes a lower redistribution structure including lower redistribution layers, lower insulating layers covering the lower redistribution layers, and a first adhesive layer between the lower insulating layers, a lower chip structure disposed on the lower redistribution structure, the lower chip electrically connected to the lower redistribution layers, conductive posts disposed on the lower redistribution structure, the conductive posts disposed around the lower chip structure, an encapsulant covering the lower chip structure and the conductive posts, an upper redistribution structure disposed on the encapsulant, the upper redistribution structure electrically connected to the conductive posts, a UBM layer disposed below the lower redistribution structure, the UBM layer electrically connected to the lower redistribution layers, and an external connection terminal electrically connected to the UBM layer. The lower redistribution layers may include a first lower redistribution layer in contact with the UBM layer, the first lower redistribution layer including a first interconnection layer and a first plating layer covering at least a portion of the first interconnection layer. The first adhesive layer may be in contact with the first plating layer of the first lower redistribution layer. A surface roughness of the first plating layer may be within a range of about 70 Å to about 160 Å.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a vertical cross-sectional view of a semiconductor package according to an example implementation;

FIG. 2 is a partially enlarged view of the semiconductor package illustrated in FIG. 1;

FIGS. 3 and 4 are vertical cross-sectional views of a semiconductor package according to example implementations;

FIG. 5 is a vertical cross-sectional view of a semiconductor package according to an example implementation;

FIG. 6 is a partially enlarged view of the semiconductor package illustrated in FIG. 5;

FIGS. 7 and 8 are vertical cross-sectional views of a semiconductor package according to example implementations;

FIG. 9 is a vertical cross-sectional view of a semiconductor package according to an example implementation; and

FIGS. 10A to 10I are vertical cross-sectional views of a method of manufacturing a semiconductor package according to an example implementation.

### DETAILED DESCRIPTION

Hereinafter, preferred example implementations of the present disclosure will be described with reference to the accompanying drawings as follows.

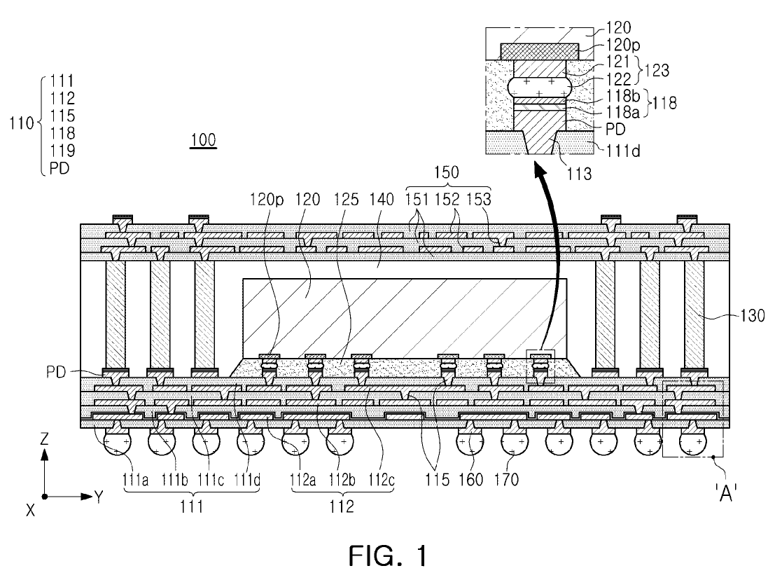

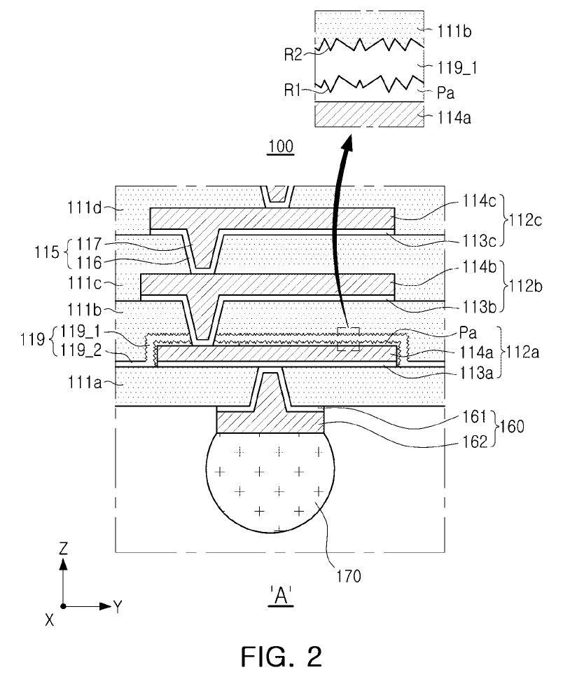

FIG. 1 is a vertical cross-sectional view of a semiconductor package according to an example implementation. FIG. 2 is a partially enlarged view of the semiconductor package illustrated in FIG. 1. FIG. 2 may correspond to region “A” of FIG. 1.

Referring to FIGS. 1 and 2, a semiconductor package 100 according to an example implementation of the present disclosure may include a lower redistribution structure 110, a lower chip structure 120, a conductive post 130, an encapsulant 140, an upper redistribution structure 150, an underbump metallurgy (UBM) layer 160, and an external connection terminal 170.

The lower redistribution structure 110 may be a support substrate on which the chip structure 120 is mounted, and may include a lower insulating layer 111, a lower redistribution layer 112, a lower redistribution via 115, a lower barrier layer 118, an adhesive layer 119, and an upper pad PD.

The lower insulating layer 111 may include an insulating resin. The insulating resin may include a thermosetting resin such as an epoxy resin, a thermoplastic resin such as polyimide, or a resin, for example, a prepreg, an Ajinomoto build-up film (ABF), FR-4, or BT, in which the thermosetting resin or the thermoplastic resin is impregnated with an inorganic filler. For example, the lower insulating layer 111 may include a photosensitive resin such as a photoimageable dielectric (PID). The lower insulating layer 111 may include a plurality of lower insulating layers 111 stacked in a vertical direction (Z-axis direction). In an example implementation, the plurality of lower insulating layers 111 may include a first lower insulating layer 111a, a second lower insulating layer 111b, a third lower insulating layer 111c, and a fourth lower insulating layer 111d stacked in the vertical direction (Z-direction).

The plurality of lower insulating layers 111 may cover the lower redistribution layer 112. The lower redistribution layer 112 may be disposed on or in the lower insulating layer 111, and may redistribute a connection pad 120P of the chip structure 120. The lower redistribution layer 112 may include, for example, a metal material including copper (Cu), aluminum (Al), silver (Ag), tin (Sn), gold (Au), nickel (Ni), lead (Pb), titanium (Ti), or alloys thereof. The lower redistribution layer 112 may perform various functions according to a design thereof. For example, the lower redistribution layer 112 may include a ground (GND) pattern, a power (PWR) pattern, and a signal (S) pattern. Here, the signal (S) pattern may be defined as a transmission path of various signals, for example, data signals or the like, excluding the ground (GND) pattern, the power (PWR) pattern, or the like.

The number of redistribution layers, included in the lower redistribution layer 112, may be greater than or less than the number of those illustrated in the drawings. In an example implementation, a plurality of lower redistribution layers 112 may include a first lower redistribution layer 112a, a second lower redistribution layer 112b, and a third lower redistribution layer 112c, stacked in the vertical direction (Z-direction). The first lower redistribution layer 112a may be covered by the first lower insulating layer 111a and the second lower insulating layer 111b, and may be disposed therebetween. The second lower redistribution layer 112b may be covered by the second lower insulating layer 111b and the third lower insulating layer 111c, and may be disposed therebetween. The third lower redistribution layer 112c may be covered by the third lower insulating layer 111c and the fourth lower insulating layer 111d, and may be disposed therebetween. Each of the lower redistribution layers 112a, 112b, and 112c may include a seed layer and an interconnection layer on the seed layer. For example, the first to third lower redistribution layers 112a, 113b, and 112c may include first to third seed layers 113a, 113b, and 113c, respectively, and may include first to third interconnection layers 114a, 114b, and 114c, respectively.

The first to third seed layers 113a, 113b, and 113c may include at least one of copper (Cu), titanium (Ti), tantalum (Ta), cobalt (Co), titanium nitride (TiN), and tantalum nitride (TaN). For example, the first to third seed layers 113a, 113b, and 113c may include a double layer of titanium (Ti) and copper (Cu). For example, the first to third interconnection layers 114a, 114b, and 114c may include a metal material including copper (Cu), aluminum (Al), silver (Ag), tin (Sn), gold (Au), nickel (Ni), lead (Pb), titanium (Ti), or alloys thereof.

In an example implementation, a surface of the first lower redistribution layer 112a may include a plurality of recesses R1. For example, the first lower redistribution layer 112a may further include a first plating layer Pa covering at least a portion of the first interconnection layer 114am the first plating layer Pa including a plurality of recesses R1. For example, the first plating layer Pa may cover an upper surface and side surfaces of the first interconnection layer 114a. The first plating layer Pa may also cover the first seed layer 113a. The first plating layer Pa may have a surface roughness Ra, greater than those of the first seed layer 113a and the first interconnection layer 114a. In an example implementation, a surface roughness of the first plating layer Pa may be less than about 160 Å. For example, a surface roughness of the first plating layer Pa may be within a range from about 10 Å to about 160 Å. For example, the surface roughness of the first plating layer Pa may be within a range from about 70 Å to about 160 Å. In an example implementation, a thickness of the first plating layer Pa may be less than about 0.1 μm. For example, a thickness of the first plating layer Pa may be within a range from about 0.01 μm to about 0.1 μm. As described above, since the first plating layer Pa may include a plurality of resources R1, such that the first plating layer Pa may not have a flat surface.

In an example implementation, the first plating layer Pa may be formed by performing a plating process on the first seed layer 113a and the first interconnection layer 114a. The first plating layer Pa may include a metal material including gold (Au), silver (Ag), nickel (Ni), or alloys thereof.

The lower redistribution via 115 may pass through the lower insulating layer 111 to electrically connect the lower redistribution layers 112 to each other. For example, the lower redistribution via 115 may interconnect the lower redistribution layers 112 having different levels. In an example implementation, the lower redistribution via 115 may have a tapered shape, decreasing downwardly. The lower redistribution via 115 may include a seed layer 116 and a via layer 117 on the seed layer 116. The seed layer 116 may include at least one of copper (Cu), titanium (Ti), tantalum (Ta), cobalt (Co), titanium nitride (TiN), and tantalum nitride (TaN). The via layer 117 may include a metal material including copper (Cu), aluminum (Al), silver (Ag), tin (Sn), gold (Au), nickel (Ni), lead (Pb), titanium (Ti), or alloys thereof.

In an example implementation, the lower redistribution via 115 may pass through the first plating layer Pa and the adhesive layer 119 to be in direct contact with an upper surface of the first interconnection layer 114a. For example, the seed layer 116 of the lower redistribution via 115 may be in contact with the upper surface of the first interconnection layer 114a.

In an example implementation, the lower redistribution via 115 may include a material, the same as that of the corresponding lower redistribution layer 112, and may be formed integrally with the corresponding lower redistribution layer 112. For example, the seed layer 116 of each lower redistribution via 115 may include a material, the same as that of the seed layers 113a, 113b, and 113c of the corresponding lower redistribution layers 112a, 112b, and 112c, and may be formed integrally with the seed layers 113a, 113b, and 113c of the corresponding lower redistribution layers 112a, 112b, and 112c. The via layer 117 of each lower redistribution via 115 may include a material, the same as that of the interconnection layers 114a, 114b, and 114c of the corresponding lower redistribution layers 112a, 112b, and 112c, and may be formed integrally with the interconnection layers 114a, 114b, and 114c of the corresponding lower redistribution layers 112a, 112b, and 112c.

The lower redistribution via 115 may include a signal via, a ground via, and a power via. The lower redistribution via 115 may be a filled via in which a metal material is filled in a via hole or a conformal via in which a metal material extends along an inner wall of a via hole.

The adhesive layer 119 may be disposed between the lower insulating layers 111. In an example implementation, the adhesive layer 119 may be disposed between the first lower insulating layer 111a and the second lower insulating layer 111b, and may cover the first lower redistribution layer 112a. For example, the adhesive layer 119 may cover side surfaces and an upper surface of the first lower redistribution layer 112a, and may extend to a space between the first lower insulating layer 111a and the second lower insulating layer 111b. A portion of the adhesive layer 119, covering the first lower redistribution layer 112a, may be referred to as a first portion 119_1, and a portion of the adhesive layer 119, extending between the first lower insulating layer 111a and the second lower insulating layer 111b, may be referred to as a second portion 119_2. In an example implementation, a surface roughness of the first portion 119_1 of the adhesive layer 119 may be greater than that of the second portion 119_2 of the adhesive layer 119.

The second portion 119_2 of the adhesive layer 119 may not have a flat surface. For example, the second portion 119_2 may include a plurality of recesses R2. In an example implementation, a surface of the first portion 119_1 of the adhesive layer 119 may not include recesses, and may be parallel to a lower surface of the lower redistribution structure 110. The adhesive layer 119 may increase bonding force between the first lower redistribution layer 112a and the lower insulating layers 111. For example, the second portion 119_2 of the adhesive layer 119 may include a plurality of recesses R2, and may be in contact with the second lower insulating layer 111b, such that an area of the adhesive layer 119 in contact with the second lower insulating layer 111b may be increased. Accordingly, bonding force between the adhesive layer 119 and the second lower insulating layer 111b may be increased, and delamination may occur between the first lower redistribution layer 112a and the lower insulating layers 111 to prevent or reduce cracks from occurring in the semiconductor package 100.

The adhesive layer 119 may be formed of a single layer or a plurality of layers. The adhesive layer 119 may include at least one of silicon oxide and silicon nitride. When the adhesive layer 119 includes silicon oxide, bonding force between the adhesive layer 119 and the second lower insulating layer 111b may further increase. For example, the second lower insulating layer 111b may have further increased bonding force with the adhesive layer 119 including an inorganic material than with a metal material such as the first lower redistribution layer 112a. When the adhesive layer 119 includes silicon nitride, a metal material of the first lower redistribution layer 112a may be prevented from being diffused into the lower insulating layers 111, thereby preventing or reducing cracks from occurring in the semiconductor package 100.

The upper pads PD may be disposed on an upper surface of the lower redistribution structure 110. The upper pads PD may be connected to the connection pad 120P of the chip structure 120 and the conductive post 130. For example, a lower barrier layer 118 may be disposed on a surface of the upper pad PD. The lower barrier layer 118 may include a material that is resistant to oxidation, for example, nickel (Ni), gold (Au), or an alloy thereof. For example, the lower barrier layer 118 may include a lower layer 118a including nickel (Ni) and an upper layer 118b including gold (Au).

The chip structure 120 may include the connection pad 120P disposed on the upper surface of the lower redistribution structure 110, the connection pad 120P electrically connected to the lower redistribution layer 112. The chip structure 120 may be an integrated circuit (IC) in a bare state in which no bump or interconnection layer is formed, but the present disclosure is not limited thereto, and may also be a packaged-type integrated circuit. The integrated circuit may be a processor chip such as a central processing unit (CPU), a graphics processing unit (GPU), a field-programmable gate array (FPGA), an application processor (AP), a digital signal processor, an encryption processor, a microprocessor, a microcontroller, or the like, but the present disclosure is not limited thereto, and may be a logic chip such as an analog-to-digital converter or an application-specific IC (ASIC), and may be a memory chip including a volatile memory such as a dynamic RAM (DRAM) or a static RAM (SRAM), and a nonvolatile memory such as a phase change RAM (PRAM), a magnetic RAM (MRAM), a dynamic RAM (RRAM), or a flash memory.

In an example implementation, the chip structure 120 may be formed of a single semiconductor chip, but the present disclosure is not limited thereto. In some example implementations, the chip structure 120 may be formed by stacking a plurality of semiconductor chips.

The chip structure 120 may include a connection bump 123 connecting the connection pad 120P to the upper pad PD of the lower redistribution layer 112. The connection bump 123 may be disposed between the upper pad PD and the connection pad 120P. For example, the connection bump 123 may include a pillar portion in contact with the connection pad 120P, and a solder portion 122 in contact with the barrier layer 115. In some example implementations, an underfill layer 125 may be disposed between the chip structure 120 and the lower redistribution structure 110. The underfill layer 125 may include an insulating resin such as an epoxy resin, and may physically and electrically protect the connection bumps 123. The underfill layer 125 may have a capillary underfill (CUF) structure, but the present disclosure is not limited thereto. In some example implementations, the underfill layer 125 may have a mole underfill (MUF) structure integrated with the encapsulant 140.

The conductive post 130 may pass through the encapsulant 140, between the lower redistribution structure 110 and the upper redistribution structure 150, and may electrically connect the lower redistribution layer 112 and an upper redistribution layer 152 to each other. The conductive post 130 may extend in a direction (Z-direction), perpendicular to the upper surface of the lower redistribution structure 110 in the encapsulant 140. An upper surface of the conductive post 130 may be exposed from the encapsulant 140, and may be coplanar with an upper surface of the encapsulant 140. For example, the conductive post 130 may have a columnar shape, passing through the encapsulant 140. However, the shape of the conductive post 130 is not limited thereto. In an example implementation, the conductive posts 130 may be disposed to surround the lower chip structure 120, and may be spaced apart from each other in an X-direction and a Y-direction.

The conductive post 130 may include a metal material such as copper (Cu). In some example implementations, a metal seed layer (not illustrated) including titanium (Ti) or copper (Cu), may be formed on a lower surface of the conductive post 130.

The encapsulant 140 may fill a space between the lower redistribution structure 110 and the upper redistribution structure 150, and may encapsulate at least a portion of each of the chip structure 120 and the conductive post 130. The encapsulant 140 may be a resin including epoxy or polyimide. For example, the resin may include a bisphenol-based epoxy resin, a polycyclic aromatic epoxy resin, an o-cresol novolac Epoxy Resin, a biphenyl-group epoxy resin, or a naphthalene-based epoxy resin. For example, the encapsulant 140 may include an EMC.

The upper redistribution structure 150 may be disposed on the chip structure 120 and the encapsulant 140, and may include an upper insulating layer 151, an upper redistribution layer 152, and an upper redistribution via 153.

The upper insulating layer 151 may include an insulating resin. The insulating resin may include a thermosetting resin such as an epoxy resin, a thermoplastic resin such as polyimide, or a resin, for example, a prepreg, an Ajinomoto build-up film (ABF), FR-4, or BT, in which the thermosetting resin or the thermoplastic resin is impregnated with an inorganic filler. The upper insulating layer 151 may include a plurality of upper insulating layers 151 stacked in a vertical direction (Z-axis direction). Depending on a process thereof, the plurality of upper insulating layers 151 may have unclear boundaries therebetween.

The upper redistribution layer 152 may be disposed on or in an upper insulating layer 151, and may redistribute the conductive posts 130. The upper redistribution layer 152 may include, for example, a metal material including copper (Cu), aluminum (Al), silver (Ag), tin (Sn), gold (Au), nickel (Ni), lead (Pb), titanium (Ti), or alloys thereof.

The number of redistribution layers, included in the upper redistribution layer 152, be greater than or less than the number of those illustrated in the drawings. For example, the upper redistribution layer 152 may include a pad portion disposed on ab upper surface of the upper redistribution structure 150. The pad portion may be physically and electrically connected to an external device.

The upper redistribution via 153 may may pass through the upper insulating layer 151, and may be electrically connected to the upper redistribution layer 152. For example, the upper redistribution via 153 may connect the upper redistribution layers 152 having different levels to each other. The upper redistribution via 153 may be a filled via in which a metal material is filled in a via hole or a conformal via in which a metal material extends along an inner wall of a via hole.

The underbump metallurgy (UBM) layer 160 may be disposed on the lower surface of the lower redistribution structure 110. The UBM layer 160 may be electrically connected to the chip structure 120 and the conductive post 130 through the lower redistribution layer 112. For example, the UBM layer 160 may be in contact with the first lower redistribution layer 112a.

The UBM layer 160 may include a seed layer 161 and a metal layer 162. The seed layer 161 may include at least one of copper (Cu), titanium (Ti), tantalum (Ta), cobalt (Co), titanium nitride (TiN), and tantalum nitride (TaN). The metal layer 162 may include, for example, a metal material including copper (Cu), aluminum (Al), silver (Ag), tin (Sn), gold (Au), nickel (Ni), lead (Pb), titanium (Ti), or alloys thereof.

The external connection terminal 170 may be disposed on the lower surface of the lower redistribution structure 110. For example, the external connection terminal 170 may be in contact with the UBM layer 160. The external connection terminal 170 may be electrically connected to the chip structure 120 and the conductive post 130 through the lower redistribution layer 112. The semiconductor package 100 may be connected to an external device, such as a module substrate, a system board, or the like, through the external connection terminal 160. For example, the external connection terminals 160 may have a combination of a pillar (or underbump metal) and a ball. The pillar may include copper (Cu) or an alloy of copper (Cu), and the ball may include a low melting point metal, for example, tin (Sn) or an alloy (Sn-Ag-Cu) including tin (Sn). In some example implementations, the external connection terminals 160 may include only the pillar or the ball. In some example implementations, a resist layer (not illustrated) may be formed on the lower surface of the lower redistribution structure 110 to protect the external connection terminals 170 from external physical and chemical damage.

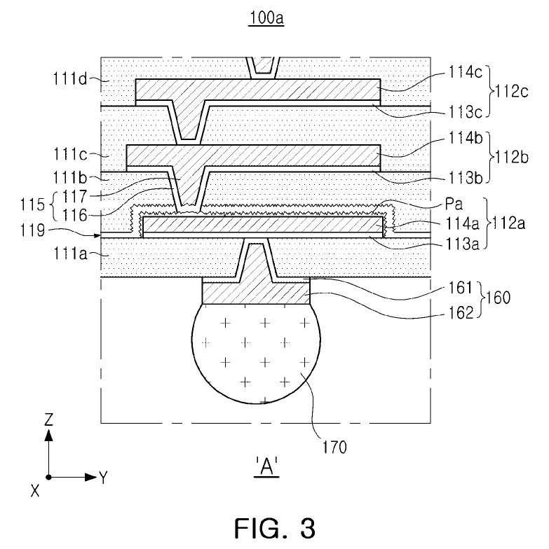

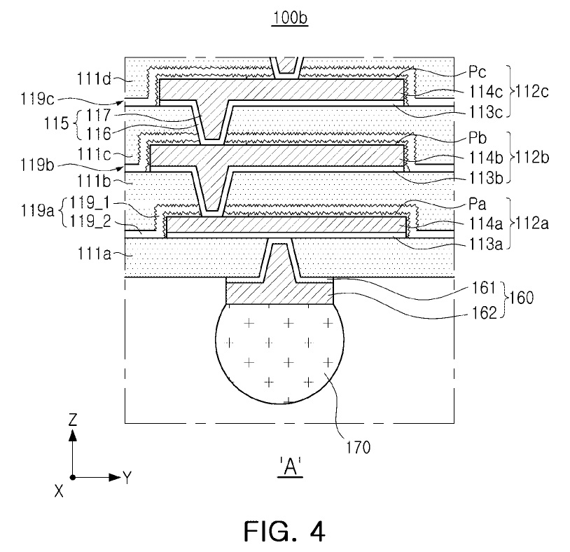

FIGS. 3 and 4 are vertical cross-sectional views of a semiconductor package according to example implementations.

Referring to FIG. 3, a semiconductor package 100a may include an adhesive layer 119 covering a lower redistribution layer 112. In an example implementation, a lower redistribution via 115 may pass through the adhesive layer 119 to be in direct contact with an upper surface of a first plating layer Pa. For example, a seed layer 116 of the lower redistribution via 115 may be in contact with an upper surface of the first plating layer Pa. In an example implementation, a surface of the lower redistribution via 115 in contact with a first lower redistribution layer 112a may include a plurality of recesses. For example, a lower surface of the lower redistribution via 115 may include a plurality of recesses. For example, lower surfaces of the seed layer 116 and the via layer 117 may include a plurality of recesses.

Referring to FIG. 4, a semiconductor package 100b may include an adhesive layer 119 covering a lower redistribution layer 112. In an example implementation, the adhesive layer 119 may include a first adhesive layer 119a, a second adhesive layer 119b, and a third adhesive layer 119c, and a first lower redistribution layer 112a, a second lower redistribution layer 112b, and a third lower redistribution layer 112c may be covered by the first adhesive layer 119a, the second adhesive layer 119b, and the third adhesive layer 119c, respectively. The first adhesive layer 119a, the second adhesive layer 119b, and the third adhesive layer 119c may have a structure, the same as or similar to that of the adhesive layer 119 described with reference to FIG. 2. For example, the second adhesive layer 119b may extend to a space between the second lower redistribution layer 112b and a third lower insulating layer 111c, and the third adhesive layer 119c may extend to a space between the third lower redistribution layer 112c and a fourth lower insulating layer 111d.

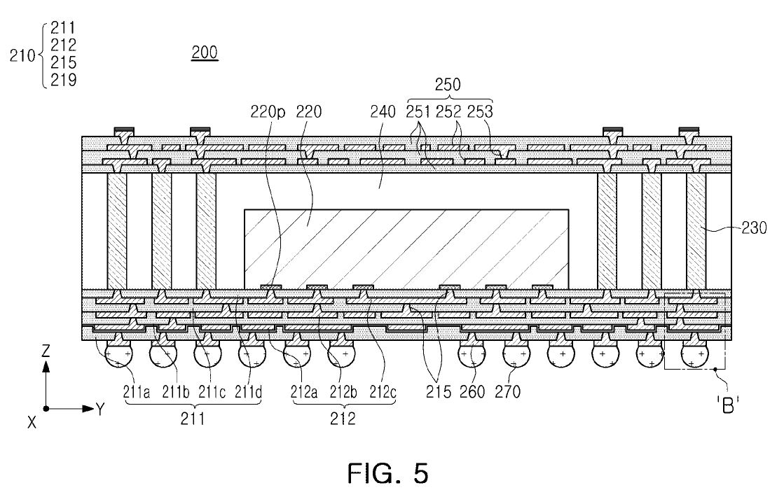

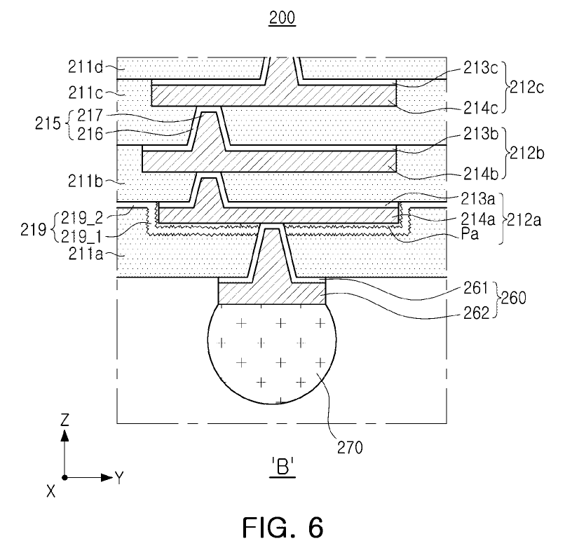

FIG. 5 is a vertical cross-sectional view of a semiconductor package according to an example implementation. FIG. 6 is a partial enlarged view of the semiconductor package illustrated in FIG. 5. FIG. 6 may correspond to region “B” of FIG. 5.

Referring to FIGS. 5 and 6, a semiconductor package 200 according to an example implementation of the present disclosure may include a lower redistribution structure 210, a lower chip structure 220, a conductive post 230, an encapsulant 240, an upper redistribution structure 250, a UBM layer 260, and an external connection terminal 270. The semiconductor package 200 according to an example implementation may have features the same or similar to those described with reference to FIGS. 1 and 2, except that the lower chip structure 220 is in contact with the lower redistribution structure 210. For example, lower surfaces of the lower chip structure 220 and the conductive post 230 may be in contact with the lower insulating layer 211. The semiconductor package 200 according to the present example implementation may be manufactured by first forming a molding structure in which the lower chip structure 220 and the conductive post 230 are encapsulated, and directly forming the lower redistribution structure 210 on one surface of the encapsulant 140 from which the lower chip structure 220 and the conductive post 230 are exposed. According to the present example implementation, the semiconductor package 200 may have a reduced thickness and excellent reliability.

The lower redistribution structure 210 may be a support substrate on which the chip structure 220 is mounted, and may include a lower insulating layer 211, a lower redistribution layer 212, a lower redistribution via 215, and an adhesive layer 219.

The first to third lower redistribution layers 212a, 212b, and 212c may include first to third seed layers 213a, 213b, and 213c, respectively, and may include first to third interconnection layers 214a, 214b, and 214c. In an example implementation, the first to third seed layers 213a, 213b, and 213c may cover upper surfaces of the first to third interconnection layers 214a, 214b, and 214c, respectively.

In an example implementation, the first lower redistribution layer 212a may further include a first plating layer Pa covering at least a portion of the first interconnection layer 214a. For example, the first plating layer Pa may cover a lower surface and side surfaces of the first interconnection layer 214a.

The lower redistribution via 215 may connect the lower redistribution layers 212 having different levels to each other. In an example implementation, the lower redistribution via 215 may have a tapered shape, upwardly decreasing. For example, a seed layer 216 of the lower redistribution via 215 may cover an upper surface of a via layer 217.

In an example implementation, the adhesive layer 219 may be disposed between a first lower insulating layer 211a and a second lower insulating layer 211b, and may cover a first lower redistribution layer 212a. For example, the adhesive layer 219 may cover side surfaces and a lower surface of the first lower redistribution layer 212a, and may extend to a space between the first lower insulating layer 211a and the second lower insulating layer 211b. A portion of the adhesive layer 219, covering the first lower redistribution layer 212a, may be referred to as a first portion 219_1, and a portion of the adhesive layer 219, extending between the first lower insulating layer 211a and the second lower insulating layer 211b, may be referred to as a second portion 219_2. In an example implementation, a surface roughness of the first portion 219_1 of the adhesive layer 219 may be greater than a surface roughness of the second portion 219_2.

The UBM layer 260 may be in contact with the first lower redistribution layer 212a. The UBM layer 260 may include a seed layer 261, covering an upper surface of a metal layer 262. In an example implementation, the UBM layer 260 may pass through the first plating layer Pa and the adhesive layer 219 to be in direct contact with a lower surface of the first interconnection layer 214a. For example, the seed layer 261 of the UBM layer 260 may be in contact with the lower surface of the first interconnection layer 214a.

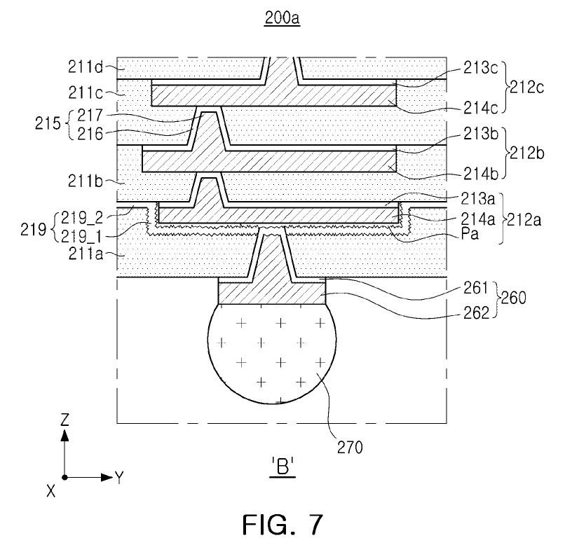

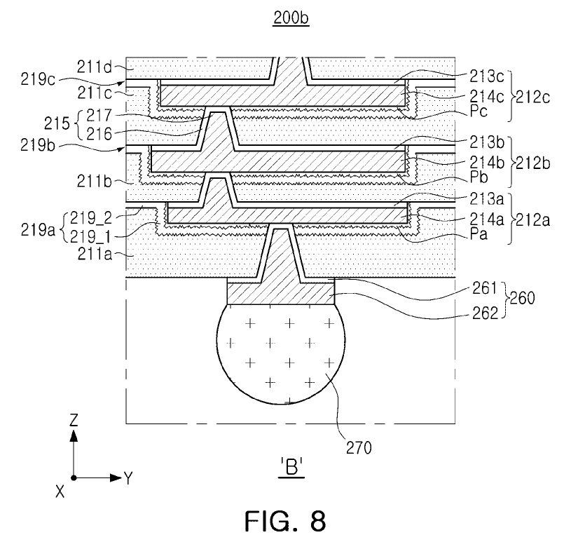

FIGS. 7 and 8 are vertical cross-sectional views of a semiconductor package according to example implementations;

Referring to FIG. 7, a semiconductor package 200b may include an adhesive layer 219 covering a lower redistribution layer 212. In an example implementation, a UBM layer 260 may pass through an adhesive layer 219 to directly contact a lower surface of a first plating layer Pa. For example, a seed layer 261 of the UBM layer 260 may be in contact with the lower surface of the first plating layer Pa. In an example implementation, a surface of the UBM layer 260 in contact with the first lower redistribution layer 212a may include a plurality of recesses. For example, an upper surface of the UBM layer 260 may include a plurality of recesses. For example, upper surfaces of the seed layer 261 and a metal layer 262 may include a plurality of recesses.

Referring to FIG. 8, a semiconductor package 200b may include an adhesive layer 219 covering a lower redistribution layer 212. In an example implementation, the adhesive layer 219 may include a first adhesive layer 219a, a second adhesive layer 219b, and a third adhesive layer 219c, and a first lower redistribution layer 212a, a second lower redistribution layer 212b, and a third lower redistribution layer 212c may be covered by the first adhesive layer 219a, the second adhesive layer 219b, and the third adhesive layer 219c, respectively. The first adhesive layer 219a, the second adhesive layer 219b, and the third adhesive layer 219c may have a structure, the same as or similar to that of the adhesive layer 219 described with reference to FIG. 2.

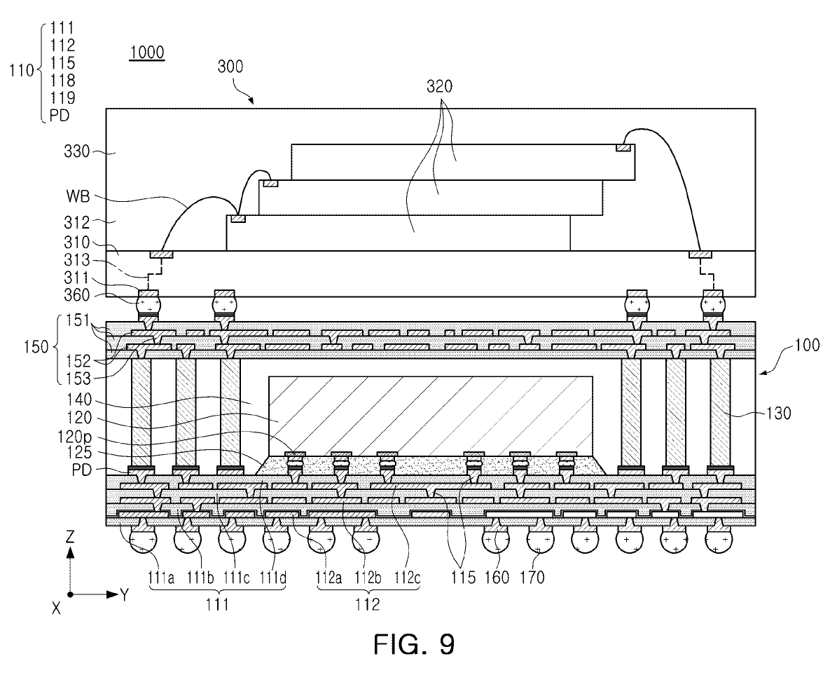

FIG. 9 is a vertical cross-sectional view of a semiconductor package according to an example implementation.

Referring to FIG. 9, a semiconductor package 1000 according to an example implementation may include a first package 100 and a second package 300. The semiconductor package 1000 is illustrated as having a configuration, the same as that of the semiconductor package 100 illustrated in FIG. 2, but the first package 100 may be replaced with the semiconductor packages 100a, 100b, 200a, 200b, and 200b described with reference to FIGS. 3 to 8, or semiconductor packages having features, similar to those of the semiconductor packages 100a, 100b, 200a, 200b, and 200b. The first package 100 and the second package 300 may be referred to as a lower package and an upper package, respectively.

The second package 300 may include a redistribution substrate 310, an upper semiconductor chip 320, and an encapsulant 330. A lower surface and an upper surface of the redistribution substrate 310 may respectively include a lower pad 311 and an upper pad 312, electrically connected to the outside. In addition, the redistribution substrate 310 may include a redistribution circuit 313, electrically connecting the lower pad 311 and the upper pad 312 to each other.

The upper semiconductor chip 320 may be mounted on the redistribution substrate 310 in a wire bonding manner or a flip-chip bonding manner. For example, a plurality of upper semiconductor chips 320 may be stacked on the redistribution substrate 310 in a vertical direction, and may be electrically connected to the upper pad 312 of the redistribution substrate 310 by a bonding wire WB. For example, the upper semiconductor chip 320 may include a memory chip, and the lower chip structure 320 may include an AP chip. The plurality of upper semiconductor chips 320 may be referred to as an upper chip structure.

The encapsulant 330 may include a material, the same as or similar to that of the encapsulant 140 of the first package 100. The second package 300 may be physically and electrically connected to the first package 100 by a conductive bump 360. The conductive bump 360 may be electrically connected to the redistribution circuit 313 in the redistribution substrate 310 through the lower pad 311 of the redistribution substrate 310. The metal bump 360 may include a low melting point metal, for example, tin (Sn) or an alloy including tin (Sn).

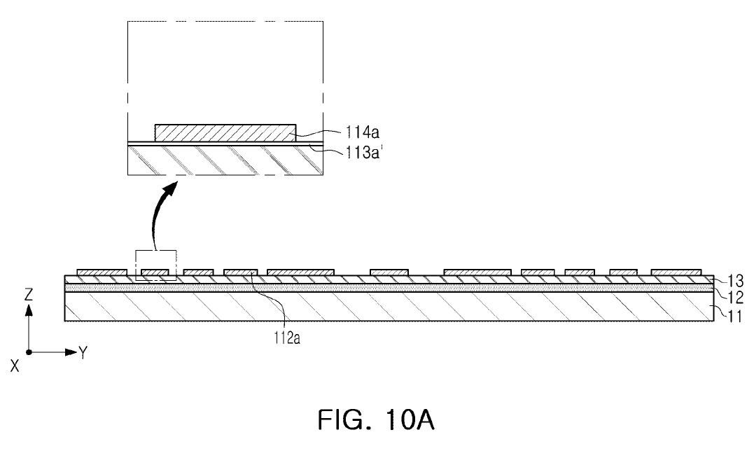

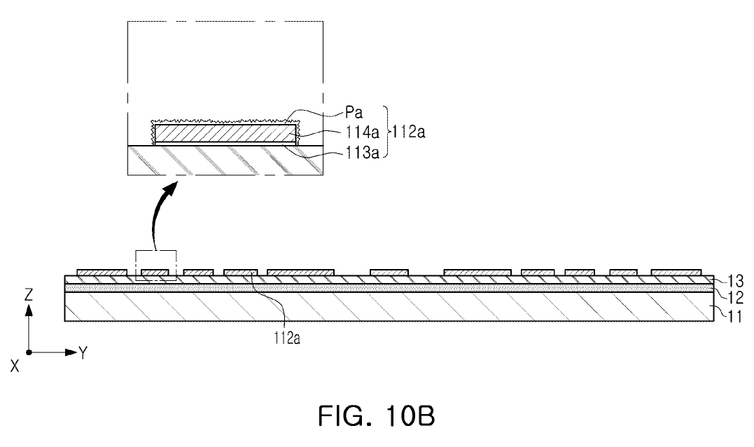

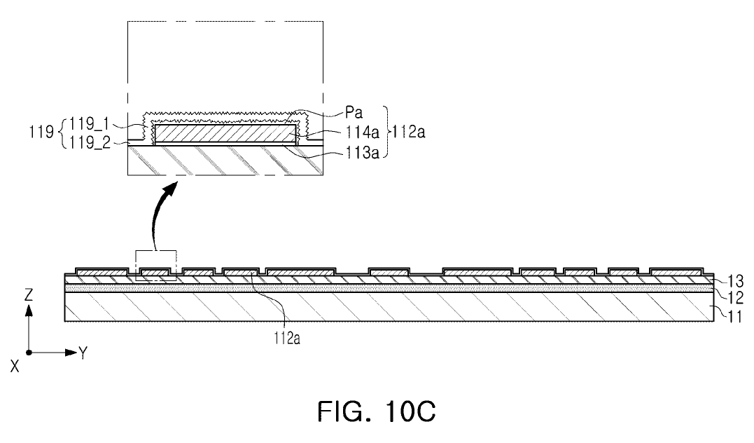

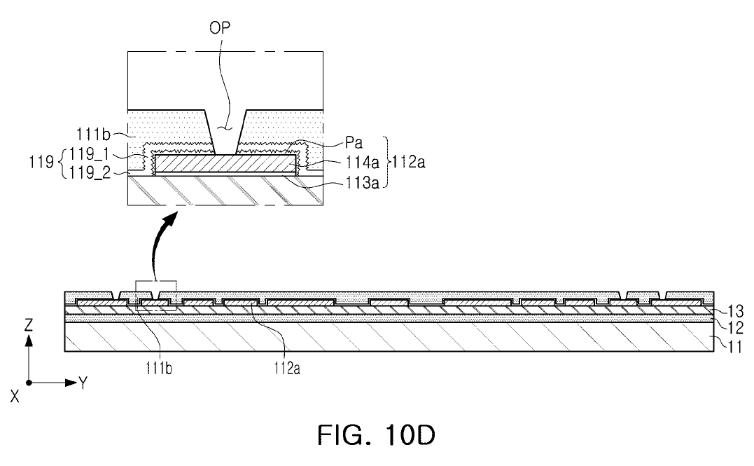

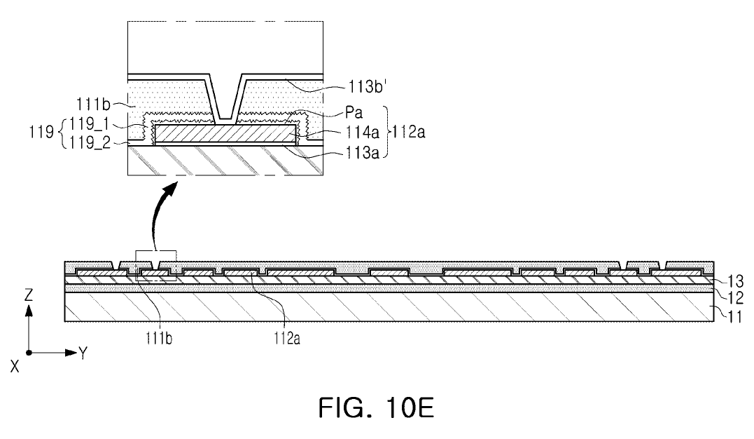

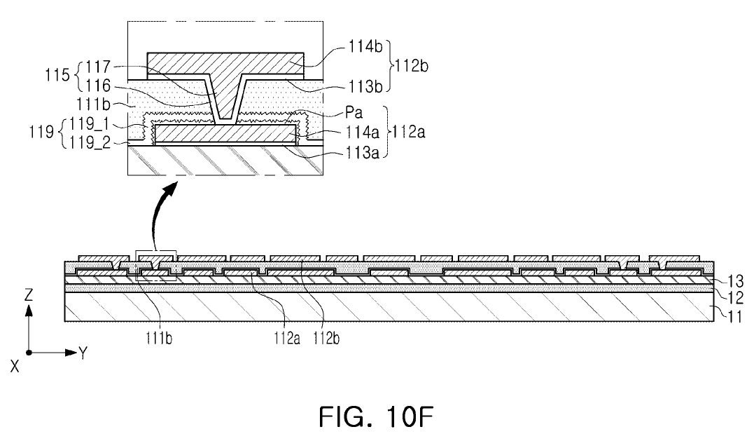

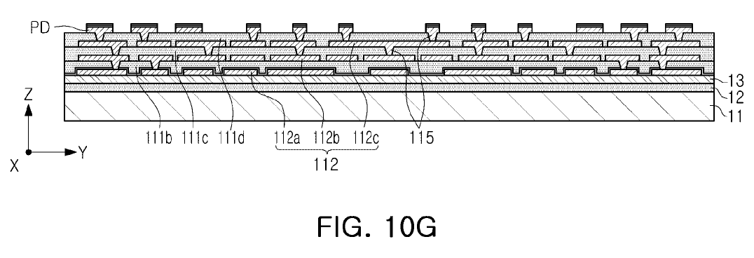

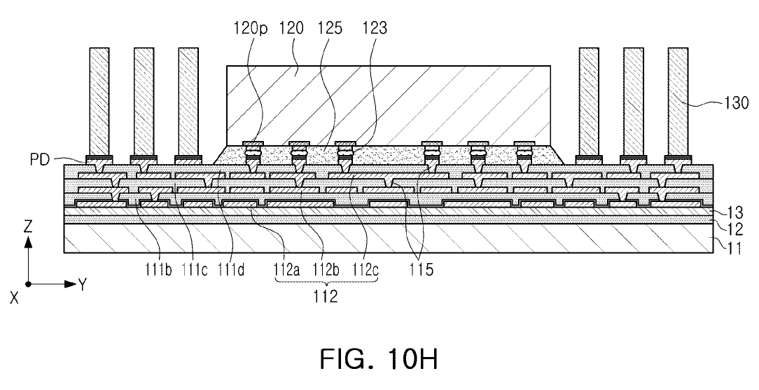

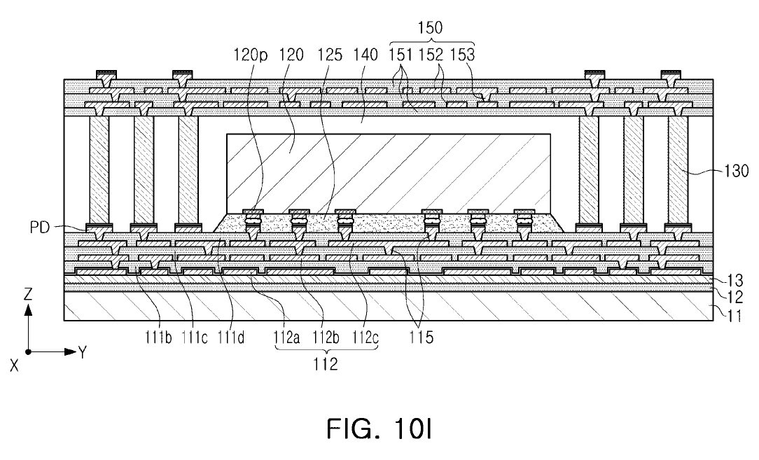

FIGS. 10A to 10I are vertical cross-sectional views of a method of manufacturing a semiconductor package according to an example implementation.

Referring to FIG. 10A, a first seed material layer 113a’ and a first interconnection layer 114a may be formed on a carrier. The carrier may include a lower layer 11, an intermediate layer 12, and an upper layer 13. The lower layer 11, the intermediate layer 12, and the upper layer 13 may include materials different from each other. For example, the lower layer 11 may be a copper clad laminate (CCL), the intermediate layer 12 may be a polymer layer including a curable resin, and the upper layer 13 may be a metal layer including nickel (Ni), titanium (Ti), or the like.

The first seed material layer 113a’ may cover an upper surface of the carrier. The first interconnection layer 114a may be formed on the carrier by forming a first seed material layer 113a’, and performing a first plating process using the first seed material layer 113a’ as a seed.

Referring to FIG. 10B, a first plating layer Pa may be formed on the first seed material layer 113a’ and the first interconnection layer 114a. The first plating layer Pa may be formed by performing a second plating process using the first seed material layer 113a’ and the first interconnection layer 114a as a seed. In an example implementation, the second plating process may be performed within a period of time, a relatively shorter than that of the first plating process. For example, the second plating process may be performed within a range of about 30 seconds to about 60 seconds. The second plating process may be performed using a current density, relatively higher than that of the first plating process. The second plating process may be performed using a high current within a relatively short period of time, such that the first plating layer Pa having a small thickness may be formed on the first seed material layer 113a’ and the first interconnection layer 114a, and a surface of the first plating layer Pa may include a plurality of recesses.

Thereafter, the first seed material layer 113a’ may be etched by performing an etching process to form a first seed layer 113a. The first plating layer Pa on the first seed material layer 113a’ may also be etched, and the first plating layer Pa may cover the first seed layer 113a and the first interconnection layer 114a. The first seed layer 113a, the first interconnection layer 114a, and the first plating layer Pa may be included in a first lower redistribution layer 112a.

Referring to FIG. 10C, an adhesive layer 119 may be formed. The adhesive layer 119 may be formed by performing a deposition process such as a chemical vapor deposition (CVD) method. The adhesive layer 119 may include an inorganic material. For example, the adhesive layer 119 may include at least one of silicon oxide and silicon nitride. The adhesive layer 119 may be formed of a single layer or a plurality of layers. A portion of the adhesive layer 119, covering the first lower redistribution layer 112a, may be referred to as a first portion 119_1, and a portion of the adhesive layer 119, not covering the first lower redistribution layer 112a, may be referred to as a second portion 119_2. In an example implementation, a surface roughness of the first portion 119_1 of the adhesive layer 119 may be greater than that of the second portion 119_2.

Referring to FIG. 10D, a second lower insulating layer 111b, covering the adhesive layer 119, may be formed. The second lower insulating layer 111b may include an organic material such as a PID. After the second lower insulating layer 111b is formed, portions of the adhesive layer 119 and the second lower insulating layer 111b may be etched to form openings OP. The openings OP may expose an upper surface of the first lower redistribution layer 112a. In an example implementation, the first plating layer Pa may be etched by performing the etching process to expose an upper surface of the first interconnection layer 114a. In an example implementation, the first plating layer Pa may not be etched, and the opening OP may expose an upper surface of the first plating layer Pa.

Referring to FIG. 10E, a second seed material layer 113b’ may be formed on the second lower insulating layer 111b. The second seed material layer 113b’ may cover an inner wall of the opening OP and an upper surface of the second lower insulating layer 111b.

Referring to FIG. 10F, a second interconnection layer 114b may be formed on the second seed material layer 113b’. The second interconnection layer 114b may be formed by performing a plating process using the second seed material layer 113b’ as a seed.

Thereafter, a second seed layer 113b may be formed by etching the second seed material layer 113b’ using the etching process. The second seed layer 113b and the second interconnection layer 114b may be included in the second lower redistribution layer 112b. A metal material, filled in the opening OP formed by performing the plating process, may be referred to as a lower redistribution via 115. The lower redistribution via 115 may include a seed layer 116 and a via layer 117 on the seed layer 116. The seed layer 116 and the via layer 117 may include a material, the same as that of the second seed layer 113b, and may be formed integrally with the second interconnection layer 114b.

Referring to FIG. 10G, the processes of FIGS. 10D to 10F may be repeatedly performed. A third lower insulating layer 111c and a fourth lower insulating layer 111d may be formed on the second lower insulating layer 111b. A third lower redistribution layer 112c may be formed on the second lower redistribution layer 112b. The first to third lower redistribution layers 112a, 112b, and 112c may be included in the lower redistribution layers 112. Lower redistribution vias 115 between the lower redistribution layers 112 may be formed together with the lower redistribution layers 112. An upper pad PD may be formed on the fourth lower insulating layer 111d.

Referring to FIG. 10H, conductive posts 130 may be formed on the upper pads PD, and the lower chip structure 120 may be mounted. The lower chip structure 120 may be mounted in a flip-chip manner. For example, connection bumps 123 and an underfill 125, covering the connection bumps 123, may be disposed between the lower chip structure 120 and the upper pads PD. The connection bumps 123 may electrically connect the connection pads 120P of the lower chip structure 120 to the upper pads PD.

Referring to FIG. 10I, an encapsulant 140, encapsulating the lower chip structure 120 and the conductive post 130, may be formed. The encapsulant 140 may be formed by coating and curing an EMC, for example. A planarization process may be performed on an upper portion of the encapsulant 140, and the conductive post 130 may be coplanar with an upper surface of the encapsulant 140.

An upper redistribution structure 150 may be formed on the conductive post 130 and the encapsulant 140. The upper redistribution structure 150 may be formed using a process similar to the processes described with reference to FIGS. 10D to 10F. The upper redistribution structure 150 may include an upper insulating layer 151, an upper redistribution layer 152, and an upper redistribution via 153.

Referring back to FIGS. 1 and 2, a lower layer 11 may be separated, and an intermediate layer 12 and an upper layer 13 may be removed to expose a lower surface of the second lower insulating layer 111b. The first lower insulating layer 111a may be formed below the second lower insulating layer 111b to form a lower redistribution structure 110. A UBM layer 160 connected to the first lower redistribution layer 112a may be formed, and an external connection terminal 170 connected to the UBM layer 160 may be formed. Thereafter, a sawing process (not illustrated) may be performed to manufacture the semiconductor package 100 illustrated in FIG. 1.

In an example implementation, an encapsulant 140, covering the lower chip structure 120 and the conductive posts 130, may be formed, and then a lower redistribution structure 110 connected to the lower chip structure 120, a UBM layer 160, and an external connection terminal 170 may be formed to manufacture the semiconductor package 200 illustrated in FIG. 5.

According to example implementations of the present disclosure, a first adhesive layer in contact with a first lower insulating layer may include a plurality of recesses on a surface thereof, thereby enhancing adhesion between the first lower insulating layer and the first adhesive layer. In addition, an adhesive layer may cover a first lower redistribution layer to prevent the diffusion of a metal material of the first lower redistribution layer, thereby preventing or reducing the occurrence of delamination between the first lower redistribution layer and the first lower insulating layer.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

What is claimed is:

1. A semiconductor package comprising:
a lower redistribution structure including lower redistribution layers, lower insulating layers respectively covering the lower redistribution layers, and a first adhesive layer between the lower insulating layers along a first direction;
a lower chip structure on the lower redistribution structure, the lower chip structure electrically connected to the lower redistribution layers;
an encapsulant covering the lower chip structure;
an underbump metallurgy (UBM) layer below the lower redistribution structure, the UBM layer electrically connected to the lower redistribution layers; and
an external connection terminal electrically connected to the UBM layer,
wherein the lower redistribution layers include a first lower redistribution layer in contact with the UBM layer, the first lower redistribution layer including a first interconnection layer and a first plating layer covering at least a portion of the first interconnection layer,
wherein the first adhesive layer is in contact with the first plating layer of the first lower redistribution layer, and
wherein a surface roughness of the first plating layer is greater than a surface roughness of the first interconnection layer.

2. The semiconductor package of claim 1, wherein the surface roughness of the first plating layer is within a range of about 70 Å to about 160 Å.

3. The semiconductor package of claim 1, wherein a surface of the first plating layer includes a plurality of recesses.

4. The semiconductor package of claim 1, wherein the first adhesive layer extends in a second direction between the lower insulating layers, the second direction being perpendicular to the first direction.

5. The semiconductor package of claim 4, wherein
the first adhesive layer includes a first portion covering the first lower redistribution layer and a second portion extending between the lower insulating layers, and
a surface roughness of the first portion is greater than a surface roughness of the second portion.

6. The semiconductor package of claim 5, wherein a surface of the second portion of the first adhesive layer includes a plurality of recesses.

7. The semiconductor package of claim 1, wherein the first plating layer of the first lower redistribution layer covers side surfaces and an upper surface of the first interconnection layer.

8. The semiconductor package of claim 1,
wherein the lower insulating layers include a first lower insulating layer in contact with the UBM layer, and a second lower insulating layer on the first lower insulating layer, and
wherein the first adhesive layer extends between the first lower insulating layer and the second lower insulating layer and between the first lower redistribution layer and the second lower insulating layer.

9. The semiconductor package of claim 8, wherein
the lower redistribution structure includes a lower redistribution via on the first lower redistribution layer, and
the lower redistribution via extends through the first plating layer to be in contact with the first interconnection layer.

10. The semiconductor package of claim 8, wherein
the lower redistribution structure includes a lower redistribution via on the first lower redistribution layer, and
a surface of the lower redistribution via that is in contact with the first lower redistribution layer includes a plurality of recesses.

11. The semiconductor package of claim 8, wherein
the lower redistribution layers include a second lower redistribution layer on the first lower redistribution layer, the second lower redistribution layer including a second interconnection layer and a second plating layer covering at least a portion of the second interconnection layer, and
the lower redistribution structure includes a second adhesive layer in contact with the second plating layer.

12. The semiconductor package of claim 1, wherein the first plating layer of the first lower redistribution layer covers side surfaces and a lower surface of the first interconnection layer.

13. The semiconductor package of claim 12, wherein
the lower insulating layers include a first lower insulating layer in contact with the UBM layer and a second lower insulating layer on the first lower insulating layer, and
the first adhesive layer extends between the first lower insulating layer and the second lower insulating layer and between the first lower redistribution layer and the first lower insulating layer.

14. The semiconductor package of claim 12, wherein
a lower surface of the first lower redistribution layer is in contact with the UBM layer, and
the UBM layer extends through the first plating layer to be in contact with the first interconnection layer.

15. The semiconductor package of claim 12, wherein
a lower surface of the first lower redistribution layer is in contact with the UBM layer, and
a surface of the UBM layer that is in contact with the first lower redistribution layer includes a plurality of recesses.

16. The semiconductor package of claim 12, wherein
the lower redistribution layers include a second lower redistribution layer on the first lower redistribution layer, the second lower redistribution layer including a second interconnection layer and a second plating layer covering at least a portion of the second interconnection layer, and
the lower redistribution structure includes a second adhesive layer in contact with the second plating layer.

17. A semiconductor package comprising:
a lower redistribution structure including lower redistribution layers, lower insulating layers respectively covering the lower redistribution layers, and a first adhesive layer between the lower insulating layers;
a lower chip structure on the lower redistribution structure, the lower chip structure electrically connected to the lower redistribution layers;
an encapsulant covering the lower chip structure;
a UBM layer disposed below the lower redistribution structure, the UBM layer electrically connected to the lower redistribution layers; and
an external connection terminal electrically connected to the UBM layer,
wherein the lower redistribution layers include a first lower redistribution layer in contact with the UBM layer,
wherein the first adhesive layer is in contact with the first lower redistribution layer,
wherein at least one surface of the first lower redistribution layer includes a plurality of recesses, and
wherein a surface of the first adhesive layer includes a plurality of recesses.

18. The semiconductor package of claim 17, wherein the first adhesive layer includes silicon nitride, silicon oxide, or a combination of silicon nitride and silicon oxide.

19. The semiconductor package of claim 17, wherein
the lower redistribution layers include a second lower redistribution layer on the first lower redistribution layer,
the lower redistribution structure includes a second adhesive layer in contact with the second lower redistribution layer, and
each of at least one surface of the second lower redistribution layer and a surface of the second adhesive layer includes a plurality of recesses.

20. A semiconductor package comprising:
a lower redistribution structure including lower redistribution layers, lower insulating layers correspondingly covering the lower redistribution layers, and a first adhesive layer between the lower insulating layers;
a lower chip structure on the lower redistribution structure, the lower chip structure electrically connected to the lower redistribution layers;
conductive posts on the lower redistribution structure and around the lower chip structure;
an encapsulant covering the lower chip structure and the conductive posts;
an upper redistribution structure on the encapsulant, the upper redistribution structure electrically connected to the conductive posts;
a UBM layer disposed below the lower redistribution structure, the UBM layer electrically connected to the lower redistribution layers; and
an external connection terminal electrically connected to the UBM layer,
wherein the lower redistribution layers include a first lower redistribution layer in contact with the UBM layer, the first lower redistribution layer including a first interconnection layer and a first plating layer covering at least a portion of the first interconnection layer,
wherein the first adhesive layer is in contact with the first plating layer of the first lower redistribution layer, and
wherein a surface roughness of the first plating layer is within a range of about 70 Å to about 160 Å.
